(19) United States
(12) Patent Application Publication
(10) Pub. No.: US 2026/0022487 A1
(43) Pub. Date: Jan. 22, 2026

(54) METHOD FOR DEPOSITING A METALLIC MATERIAL ON A SURFACE OF AT LEAST ONE SUBSTRATE

(71) Applicant: SUNDRIVE SOLAR PTY LTD, Kurnell (AU)

(72) Inventors: Alison Joan Lennon, Kurnell (AU); Storm Drury, Kurnell (AU); Peter Buggs, Kurnell (AU); Matthew Eyles, Kurnell (AU); Lalith Vudata, Kurnell (AU); Jonathan Bruck, Kurnell (AU)

(21) Appl. No.: 19/338,913

(22) Filed: Sep. 24, 2025

Related U.S. Application Data
(63) Continuation-in-part of application No. PCT/AU2024/050262, filed on Mar. 22, 2024.

(30) Foreign Application Priority Data
Mar. 24, 2023 (AU) 2023900831

(51) Int. Cl. C25D 7/12; C25D 17/06; H10F 71/00

(52) U.S. Cl. CPC C25D 7/126; C25D 17/06; H10F 71/135

(57) ABSTRACT

A method for depositing a metallic material on a surface of a substrate comprising the steps of: providing the substrate having opposite first and second major surfaces; providing an arrangement for depositing a metallic material on a surface of the substrate, the arrangement comprising: a support structure having an electrode, a counter electrode, and an electrolyte for depositing metal ions onto one or more portions of the first major surface of the at least one substrate; attaching the substrate to the support structure wherein the electrode is in electrical contact with the substrate; contacting the substrate and the counter electrode with the electrolyte; and thereafter passing an electrical current through the electrolyte between the first major surface of the at least one substrate and the counter electrode such that the metallic material is deposited at at least some areas of the first major surface of the at least one substrate.

### CROSS-REFERENCE TO RELATED APPLICATIONS

This application is a continuation-in-part of PCT Patent Application No. PCT/AU2024/050262, filed on Mar. 22, 2024, which claims priority to Australian Patent Application No. 2023900831, filed on Mar. 24, 2023, the content of all of which is incorporated herein by reference.

### TECHNICAL FIELD

The present disclosure relates generally to a method for depositing a metallic material on a surface of a substrate. The present disclosure relates particularly, though not exclusively, to a method for electrodepositing a pattern of metallic contacts on a surface of a substrate, the pattern of a metallic contacts enabling electrical current to be conducted to and/or from the substrate.

### BACKGROUND

The electronic, semiconductor and photovoltaic (PV) industries often require the need to plate a substrate with a conductive material. However, there are many issues that remain in trying to plate a substrate, for example, material choice, cost, reliability of the plating process and the resulting plated substrate, and so on. There is therefore a need to provide better plating methods.

PV cells, also sometimes referred to solar cells, are one type of material that has a substrate that requires plating with a conductive material. Issues associated with plating a substrate to form a PV cell will now be described, though it should be appreciated that the issues also apply to substrates used in the electronic and semiconductor industries.

PV cells absorb light and generate photovoltages and photocurrents. Typically, a source of the light is the sun and so PV cells are commonly referred to as solar cells. In order to extract the electrical current from a solar cell, a pattern of a metallic material is formed on each of the semiconductor polarities of the solar cell. Solar cells can then be interconnected into an electrical circuit to derive a source of electrical power. Most solar cells are designed so that their different semiconductor polarities are formed on the different surfaces of the solar cell, however in some solar cell designs, both the positive and negative polarities are formed on the same surface thereby leaving the front surface of the solar cell free of metal and able to maximize absorption of incoming light energy.

Today most solar cells which are industrially produced are fabricated on silicon wafers and use silver to form the pattern of a metallic material on solar cell surfaces. Silver particles are combined into a viscous paste which is screen printed on a solar cell surface. The printed paste is then fired at temperatures typically exceeding 600° C. to form a pattern of a metallic material which adheres strongly to the solar cell surface and provides the electrical contacts for the solar cell. For fabricating other types of solar cells, which may be more sensitive to temperature, only moderate heat can be used (i.e., <250° C.) and additives must be used to ensure strong adhesion of the paste to the solar cell surface. However, silver is a costly metal and the continued use of silver for solar cell manufacturing may deplete global reserves. For these reasons, it is desirable to replace the silver with a more abundant metal such as copper.

Copper is a lower cost and more abundant metal; however, it is not easily incorporated into a paste which can be screen printed due to its tendency to oxidise. Although this oxidation can be largely addressed by capping the copper particles with a silver layer, this approach can require up to 50% of the particle weight to be silver. This means that, if large volumes of solar cells are to be manufactured, then the supply and cost of silver will remain a critical problem for manufacturers.

Another low-silver usage option is to form the copper electrode pattern by electroplating using an electrolyte comprising a source of copper ions. This approach has the benefit, that the pattern of a metallic material does not contain any binders or additives and consequently has a much higher conductivity than any silver or copper/silver patterns produced by screen printing of pastes. However, electroplating requires an additional masking step to define the electrode pattern. All areas of the solar cell surface, on which metal is not required, need to be covered with either an inorganic masking material such as SiNₓ or SiOₓ or an organic masking material such as a resin or hot melt ink.

Earlier metal (e.g., copper) electroplating methods for forming solar cells adopted two general types of approaches. These approaches can be classified as vertical clip-based methods and horizontal methods.

The known vertical clip-based methods essentially follow the method of industrial electroplating of metal workpieces, semiconductor wafers and printed circuit boards. This general approach is now described with reference to FIG. 1A. FIG. 1A schematically illustrates a solar cell 135 with a masking layer 125 with openings applied to both major surfaces of the solar cell. The solar cell 135 is conveyed through a plating bath 100 comprising of plating electrolyte 120.

The electrical current for the electroplating process is provided by one or more electrode clips 110 which suspend the solar cell 135 vertically. The clips 110 electrically contact regions of a conductive layer on the solar cell (130 in FIG. 1A), these regions being exposed through openings which have been made in the masking layer 125 by a previous patterning process. The conductive layer 130, which is typically called a “seed layer”, carries current to all the other surface regions which are exposed to the plating electrolyte 120 through other openings in the masking layer 125 allowing those regions to be electroplated. The conductive layer 130 must therefore extend under the masking material 125 over the full area of the solar cell 135 to ensure that those surface regions of the solar cell 135 furthest from the electrode clip 110 can be electroplated with the same material properties (e.g., metal finger height). The seed layer 130 needs to be applied or deposited in an additional step, which typically requires a physical vapour deposition (PVD) process, to enable electroplating using this method. Once the electroplating step has been completed, the seed layer 130 must then be removed from the wafer surface. The requirement for a seed layer adds to the process cost, complexity and creates additional waste. Additionally, the PVD method used to deposit the seed layer 130 can damage the solar cell 135 resulting in a metallised solar cell with a lower energy conversion efficiency.

A further problem for this vertical approach is that, with larger and thinner wafers, the vertical suspension and the conveying of the solar cells in a plating bath can result in wafer breakage. The wafers used for solar cells are currently ˜160 μm thick and are expected to reduce to ˜100 μm within the next 10 years to reduce material usage.

In addition to reducing thickness, the wafer size being used for solar cells is increasing. Wafers as large as 210 mm are now routinely being used for solar cells, whereas the earlier solar cells were half this size. This makes the vertical conveying through a plating bath challenging, especially when the wafers must pass through sluices and/or weirs for rinsing and/or subsequent plating steps. The larger wafers also place a higher requirement on the thickness of the seed layer as the electrical current needs to be conducted from the electrode clips 110 to all surface portions of the larger wafer without resistive electrical power loss.

Other problems which often arise with this vertical electroplating approach are: (i) the need to remove undesirable metallic materials which deposit on the electrode clips 110; and (ii) difficulties in aligning the electrode clips 110 to very small openings in a plating mask 125 which is formed over the solar cell 135 surface. These factors increase the complexity of the design of vertical plating tools for solar cells. The conveying return process is typically required for the removal of plated metal from the electrode clips 110 and automation of wafer loading requires very careful alignment of the clips to small contact regions on the solar cell. In addition, frequently a frame, or an equivalent guide or barrier is applied around the solar cell to prevent copper from plating at the edges of the solar cell. This frame can reduce the frequency of wafer breakage as the solar cells are conveyed through the bath, however it complicates the automated loading of solar cells in a plating tool.

There are, however, a number of advantageous features of this vertical electroplating approach including: (i) small equipment footprint (especially as wafer areas increase); (ii) ability to use insoluble anodes (115 in FIG. 1A) for a faster electroplating rate; and (iii) the potential to be able to plate both major solar cell surfaces at the same time. The latter attribute is particular advantageous as the power generation per unit area increases for bifacial solar PV modules, which can absorb light from both sides. Such modules are becoming increasingly desirable, especially for non-rooftop installations.

The second known approach, which has been used for solar cell plating, is to convey the solar cells in a horizontal orientation along a sequence of rollers or other conveying mechanisms with the under major surface of the solar cell in contact with the electrolyte containing metal ions and the upper major surface of the solar cell being maintained essentially dry. This process is now described in more detail with reference to FIG. 1B. Electrical contact to the solar cell 135 for this horizontal approach is established via the upper conductive dry surface using a brush, roller or other electrode contact 155. Unlike the above-described vertical plating approach, this method is typically deployed to form a contact pattern of a metallic material on just one surface of the solar cell and thus results in monofacial solar cells.

An electrical current can be provided to the under surface solar cell regions exposed to the electrolyte through the openings of a mask layer 125 using light to induce a photocurrent in the solar cell and make the n-type surface of a semiconducting solar cell cathodic. This process is referred to as light-inducing plating and is described in more detail in: A Lennon et al., Evolution of metal plating for silicon solar cell metallization, Progress in Photovoltaics, 21(7), 1454-1468, 2012.

Light sources 175 are typically placed within the plating bath 150 and utilize a wavelength range which is optimally absorbed by the solar cell. The electrode contact on the upper dry side of the solar cell completes the circuit with a connection to a power source and anode. The current/voltage of the plating process can then be controlled by the power source.

Horizontal plating can also be used to form a metal electrode pattern on the p-type surface of a solar cell by inducing a current in the solar cell in the forward bias direction. This process may be referred to as “forward bias plating” and is disclosed in PCT international publication number WO2011117797.

Bifacial solar cells can be plated by performing light induced plating and forward-bias plating in two separate plating steps. This two-step process reduces the processing throughput and increases the wafer handling compared to what can be achieved with a vertical plating approach such as described with reference to FIG. 1A.

There are a number of other disadvantageous features of horizontal plating tools. First, because the anode 170 is typically placed at the bottom of plating bath 150, it is difficult to use insoluble anodes due to the generation of bubbles of gas collecting on the solar cell (under) surface to be plated. Instead, sacrificial (soluble) anodes must typically be used. Because of the limited corrosion rates of soluble anodes, the plating rate is typically limited to values of ˜40 mA/cm². Second, the horizontal plating method requires that the (top) surface of the solar cell, not being metallised, is maintained dry. This can complicate the design of the plating equipment. Finally, the conveying of solar cells in a horizontal orientation can increase the required equipment footprint. This is especially disadvantageous if equipment must be duplicated (for the one-sided process) to achieve a desired manufacturing capacity.

However, a key advantage of the horizontal plating method is that a seed layer is not required to conduct current along the surface to be plated. Instead for the plating of metal such as copper to both the n-type and p-type surfaces of a solar cell, the current passes through the solar cell perpendicular to the solar cell surfaces. This can reduce the material cost required to produce a metal electrode pattern on a solar cell surface.

Both described solar cell plating methods have disadvantages and there is a need for improvement.

### SUMMARY

An embodiment provides a method for depositing a metallic material on a surface of at least one substrate, the method comprising the steps of:
providing the at least one substrate having opposite first and second major surfaces;
providing an arrangement for depositing a metallic material on a surface of the at least one substrate, the arrangement comprising: a support structure having an electrode, a counter electrode, and an electrolyte suitable for depositing metal ions onto one or more portions of the first major surface of the at least one substrate;
attaching the at least one substrate to the support structure such that the electrode is in electrical contact with the at least one substrate;
contacting the at least one substrate and the counter electrode with the electrolyte; and thereafter
passing an electrical current through the electrolyte between the first major surface of the at least one substrate and the counter electrode such that the metallic material is deposited at least some areas of the first major surface of the at least one substrate.

The substrate may include an organic-glass-, silicon- or metal-based substrate. The substrate may include a solar cell.

The step of contacting the at least one substrate and the support structure such that the electrode is in electrical contact with the at least one substrate may allow current to flow from the second major surface through the at least one substrate to the first major surface or around the at least one substrate such that current flows from the electrode to the first major surface (i.e. not through the at least one substrate). The specific mode of current flow will depend on the type of substrate and required plating process. For example, conductive substrates may allow for current flow through the substrate, whereas non-conductive substrate may require current flow around the substrate.

In an embodiment, the electrode is in electrical contact with a surface of the at least one substrate. A surface of the at least one substrate may include a conductive seed layer and the electrode may be electrically connected to the conductive seed layer.

The step of contacting the at least one substrate and the counter electrode with the electrolyte may include immersing the support structure either partially or fully in the electrolyte. In an embodiment, contacting the at least one substrate and the counter electrode with the electrolyte may be done in a manner such that a surface normal of the first major surface of the at least one substrate is directed in a direction transversal to the direction of gravity. In an embodiment, contacting the at least one substrate and the counter electrode with the electrolyte may be done in a manner such that a surface normal of the first major surface of the at least one substrate is directed in a direction parallel to the direction of gravity.

The at least one substrate may be contacted with the electrolyte in a manner such that the first major surface of the at least one substrate is oriented in a vertical orientation and substantially along the direction of gravity. The at least one substrate may be contacted with the electrolyte in a manner such that the first major surface of the at least one substrate is oriented in a direction transversal to the direction of gravity.

The arrangement may comprise a voltage source and wherein a magnitude of the electrical current passing through the electrolyte between the electrode and the counter electrode is determined by the voltage source. The electrode may be electrically coupled to a negative terminal of the voltage source and the counter electrode may be electrically coupled to a positive terminal of the voltage source. The counter electrode may be a soluble electrode and may provide a source of metal ions for the metal deposition on the one or more portions of the first major surface of the at least one substrate. The counter electrode may be an insoluble electrode. The surface of the counter electrode may be coated with a metal oxide or combination of metal oxides such as titanium oxide, ruthenium oxide, iridium oxide or tantalum oxide.

The first major surface of the at least one substrate may have an n-type polarity. The first major surface of the at least one substrate may be covered with a masking material which may at least largely insoluble in the electrolyte and one or more portions of the first major surface of the at least one substrate may contact the electrolyte through openings in the masking material. The electrode may include a contact that contacts the first major surface of the at least one substrate. The electrode may include an electrically conductive surface portion has a substantially planar surface portion.

In an embodiment, the method may further comprise applying a sealing material at an edge region of the at least one substrate whereby a seal is established which prevents penetration of the electrolyte to at least a portion of the second major surface of the at least one substrate. The sealing material may be applied at an edge surface region of the first major surface of the at least one substrate. The sealing material may be applied at an edge surface region of the second major surface of the at least one substrate. The support structure may include a groove at an edge portion of the substrate. A portion of the sealing material may be positioned within the groove. The first major surface of the at least one substrate may be coated with a transparent conductive oxide (TCO) material.

In an embodiment, the electrode is one of two or more electrodes. In an embodiment, the method comprises: providing two or more substrates each having opposite first and second major surfaces; attaching the two or more substrates to the support structure such that each electrode of the two or more electrodes is in electrical contact with one of the two or more substrates; contacting the two or more substrates and the counter electrode with the electrolyte; and passing an electrical current through the electrolyte between the first major surface of each substrate and counter electrode such that the metal is deposited at at least some areas of the first major surface of each substrate. The at least two substrates may be positioned such that the second surfaces of at least two substrates face in opposite directions.

The metallic material may comprise copper.

An embodiment provides a method for depositing a metallic material on a surface of at least one solar cell, the method comprising the steps of:
providing the at least one solar cell having opposite first and second major surfaces;
providing an arrangement for depositing a metallic material on a surface of the at least one solar cell, the arrangement comprising: an electrode structure having an electrically conductive surface portion, a counter electrode and an electrolyte suitable for depositing metal ions onto one or more portions of the first major surface of the at least one solar cell;
attaching the second major surface of the at least one solar cell and the electrically conductive surface portion of the electrode structure to each other such that the electrically conductive surface portion of the electrode structure is positioned over at least the majority of the second major surface of the at least one solar cell and the electrically conductive surface portion of the electrode structure is in direct or indirect electrical contact with, and supports, the at least one solar cell;
immersing the electrode structure with the at least one solar cell and the counter electrode in the electrolyte in a manner such that a surface normal of the first major surface of the at least one solar cell is directed in a direction transversal to the direction of gravity; and thereafter
passing an electrical current through the electrolyte between the first major surface of the at least one solar cell and the counter electrode such that the metal is deposited at least some areas of the first major surface of the at least one solar cell.

The at least one solar cell may be immersed in the electrolyte in a manner such that the first major surface of the at least one solar cell is oriented in a vertical orientation and substantially along the direction of gravity.

In one embodiment the arrangement comprises a voltage source and a magnitude of the electrical current passing through the electrolyte between the electrode structure and the counter electrode is determined by the voltage source. The electrode structure maybe electrically coupled to a negative terminal of the voltage source and the counter electrode is electrically coupled to a positive terminal of the voltage source.

The counter electrode may be a soluble electrode and may provide a source of metal ions for the metal deposition on the one or more portions of the first major surface of the at least one solar cell. Alternatively, the counter electrode may be an insoluble electrode and the surface of the counter electrode may be coated with a metal oxide or combination of metal oxides such as titanium oxide or tantalum oxide.

The first major surface of the at least one solar cell may have an n-type polarity. The at least one solar cell may be forward-biased to allow metal to deposit on one or more portions of the n-type surface of the solar cell. The forward bias may be result of an electrical charge generated by absorption of light by the at least one solar cell. The arrangement may comprise a light source arranged to generate the light for absorption by the at least one solar cell.

The first major surface of the at least one solar cell may be covered with a masking material which is at least largely insoluble in the electrolyte and one or more portions of the first major surface of the at least one solar cell may be immersed in the electrolyte through openings in the masking material.

The electrically conductive surface portion may have a substantially planar surface portion.

In one embodiment a sealing material is applied at an edge region of the at least one solar cell and a portion of the electrode structure whereby a seal is established which prevents penetration of the electrolyte to at least a portion of the second major surface of the at least one solar cell. The sealing material may be applied at an edge surface region of the first major surface of the at least one solar cell and/or at an edge surface region of the second major surface of the at least one solar cell. The sealing material maybe, or may contain, a polymeric material, such as a thermoplastic polymeric material. The polymeric material may comprise a phenolic resin.

One or more embodiments may provide significant practical advantages and enable deposition of metallic material on selected major surfaces of solar cells a high throughput. An insoluble electrode may be used even when only one of the major surfaces of the solar cell is exposed to the electrolyte. As the solar cells may be in a substantially vertical orientation, the generation of “gas bubbles” at the electrode is not critical. Further, the seal prevents penetration of the electrolyte to at least a portion of the second major surfaces of the solar cells, even when the solar cells is substantially vertically oriented. In addition, the seal may be positioned to prevent depositing the metallic material at edge regions of the solar cell, which presents a further advantage. Further, the seal may be composed of a material which is compatible with a masking material, which has the advantage that a large fraction of the seal together with the masking material may be recovered after depositing the metallic material.

The first major surface of the at least one solar cell may be coated with a transparent conductive oxide (TCO) material.

In one embodiment the electrically conductive surface portion of the electrode structure is one of two or more electrically conductive surface portions and the method comprises:
providing two or more solar cells each having opposite first and second major surfaces;
attaching each second major surface of the two or more solar cells to at least one electrically conductive surface portion of the electrode structure such that each electrically conductive surface portion of the electrode structure is in direct or indirect electrical contact with the second major surface of at least one solar cell;
immersing the electrode structure with the two or more solar cells and the counter electrode in the electrolyte in a manner such that a surface normal of the first major surface of each solar cell is directed in a direction transversal to the direction of gravity; and
passing an electrical current through the electrolyte between the first major surface of each solar cell and counter electrode such that the metal is deposited at at least some areas of the first major surface of each solar cell.

The at least two solar cells may be positioned such that the second surfaces of at least two solar cells face in opposite directions. The electrically conductive surface portions of the electrode structure may be surfaces of a substantially planar electrode having two opposite major surfaces which the second surfaces of two solar cells may face and over which the second surfaces of the two solar cells may be positioned. Further, the electrically conductive surface portion of the electrode may comprise graphite. An advantage of forming the conductive plate 232 from graphite is that elastic modulus of graphite is typically <50 GPa, where harder electrode materials such as stainless steel can have elastic moduli exceeding 200 GPa. The metallic material comprises copper.

The surface portion of the electrode structure may have a groove at the edge portion of the solar cell. A portion of the sealing material may be positioned within the groove. The groove may have an extension which undercuts the edge portion of the solar cell. A further sealing material may be positioned within the extension of the groove. The further sealing material may be electrically conductive and may contain graphite, which provides the advantage that the electrical current can be more effectively delivered to the edge regions of the at least one solar cell.

An embodiment provides a substrate having a metallic material on a surface deposited by the method in as set forth above. The substrate may include an organic-glass-, silicon- or metal-based substrate. The substrate may include a solar cell.

An embodiment provides a method of forming a seal between a substrate and a structure; the method comprising the steps of:
providing the substrate having first and second major surfaces;
positioning the substrate relative to a surface of the support structure such that a seal can be formed between the surface of the support structure and at least one of the first major and the second major surface of the substrate; and
depositing at least one material at an edge portion of the substrate and the surface of the support structure and forming a solid polymeric bead from the at least one material and which surrounds at least a portion of at least one major surface of the substrate whereby a seal is established which prevents penetration of a fluid, such as an electrolyte, to an area of the second major surface of the substrate which is surrounded by the seal.

The at least one deposited material may include or contain polymeric material. Additionally or alternatively, the at least one material may include or contains a monomeric material. The at least one material may also include or contain a polymerisation initiator which reacts with the monomeric material to form a polymeric material which solidifies on the surface of the substrate and structure to form the polymeric bead.

The formed solid polymeric bead material may be exposed to heat treatment above the softening temperature of the solid polymeric bead in a manner such that polymeric chains become cross-linked.

The at least one material may be deposited at a temperature above a softening temperature of the solid polymeric bead that is being formed. For example, the at least one material may be deposited at a temperature in the range of 80 and 120° C.

The solid polymeric bead may include or contain a thermoplastic polymeric material.

Forming the solid polymeric bead may comprise allowing cooling of the at least one material to a temperature below the softening temperature of the solid polymeric bead. The at least one material may be deposited at a temperature of at a temperature of at least 70° C.

The surface of the support structure may be substantially planar.

The at least one material may comprise a phenolic resin in a solvent or mixture of a plurality of solvent materials. For example, the at least one material may include a solution which includes a polymer and a weight fraction of the polymer in the solution is between 60 and 95% by weight, such as between 75 and 85% by weight. Further, the at least one material may include a solvent of a solution which includes at least one of: butyl acetate, dipropylene glycol methyl ether, diethylene glycol, ethyl acetate, ethyl lactate, ethylene glycol, glycerol, isopropanol, N-methylpyrrolidone, N, N-dimethylformamide, propylene glycol, propylene glycol methyl ether, propylene glycol methyl ether acetate, triethylene glycol.

The solid polymeric bead may have a width of between 1 and 5 mm, such as between 1 and 3 mm.

The surface of the support structure may have a groove at the edge portion of the substrate and a portion of the solid polymeric bead may be positioned within the groove. The groove may have an extension which undercuts the edge portion of the substrate. A further sealing material may be positioned within the extension of the groove. The further sealing material may be electrically conductive and contains graphite.

An embodiment provides a method of forming a seal between a solar cell and a structure; the method comprising the steps of:
providing the solar cell having first and second major surfaces;
positioning the solar cell relative to a surface of the structure such that a seal can be formed between the surface of the structure and at least one of the first major and the second major surface of the solar cell; and
depositing at least one material at an edge portion of the solar cell and the surface of the structure and forming a solid polymeric bead from the at least one material and which surrounds at least a portion of at least one major surface of the solar cell whereby a seal is established which prevents penetration of a fluid, such as an electrolyte, to an area of the second major surface of the solar cell which is surrounded by the seal.

The at least one deposited material may include or contain polymeric material. Additionally or alternatively, the at least one material may include or contains a monomeric material. The at least one material may also include or contain a polymerisation initiator which reacts with the monomeric material to form a polymeric material which solidifies on the surface of the solar cell and structure to form the polymeric bead.

The formed solid polymeric bead material may be exposed to heat treatment above the softening temperature of the solid polymeric bead in a manner such that polymeric chains become cross-linked.

The at least one material may be deposited at a temperature above a softening temperature of the solid polymeric bead that is being formed. For example, the at least one material may be deposited at a temperature in the range of 80 and 120° C.

The solid polymeric bead may include or contain a thermoplastic polymeric material.

Forming the solid polymeric bead may comprise allowing cooling of the at least one material to a temperature below the softening temperature of the solid polymeric bead. The at least one material may be deposited at a temperature of at a temperature of at least 70° C.

The surface of the structure may be substantially planar and the structure may be an electrode structure.

The at least one material may comprise a phenolic resin in a solvent or mixture of a plurality of solvent materials. For example, the at least one material may include a solution which includes a polymer and a weight fraction of the polymer in the solution is between 60 and 95% by weight, such as between 75 and 85% by weight. Further, the at least one material may include a solvent of a solution which includes at least one of: butyl acetate, dipropylene glycol methyl ether, diethylene glycol, ethyl acetate, ethyl lactate, ethylene glycol, glycerol, isopropanol, N-methylpyrrolidone, N, N-dimethylformamide, propylene glycol, propylene glycol methyl ether, propylene glycol methyl ether acetate, triethylene glycol.

The solid polymeric bead may have a width of between 1 and 5 mm, such as between 1 and 3 mm.

The surface of the structure may have a groove at the edge portion of the solar cell and a portion of the solid polymeric bead may be positioned within the groove. The groove may have an extension which undercuts the edge portion of the solar cell. A further sealing material may be positioned within the extension of the groove. The further sealing material may be electrically conductive and contains graphite.

An embodiment provides a substrate sealed to a structure using the method as set forth above.

### BRIEF DESCRIPTION OF THE DRAWINGS

Embodiment will be more fully understood from the following description of exemplary embodiments of the disclosure. The description is provided with reference to the accompanying non-limiting drawings.

FIG. 1A is a schematic cross-sectional representation of a vertical solar cell plating arrangement cell plating arrangement (prior art);

FIG. 1B is a schematic cross-sectional representation of a horizontal solar cell plating arrangement (prior art);

FIG. 2A is a schematic cross-sectional representation of an arrangement for forward-bias plating of p-type surface portions of two solar cells on a vertically oriented cathode plate in accordance with an embodiment;

FIG. 2B is a schematic cross-sectional representation of an arrangement for light-induced plating of n-type surface portions of two solar cells on a vertically oriented cathode plate in accordance with an embodiment;

FIG. 3 is a schematic representation of a cathode plate of a plating arrangement, holding a solar cell, in accordance with an embodiment;

FIGS. 4A, 4B and 4C are cross-sectional representations of an edge region of a solar cell sealed to a cathode plate using different sealing arrangements in accordance with embodiments;

FIG. 5A and FIG. 5B are schematic representations of a series of cathode plates with solar cells sealed on a first major surface of the cathode plates being conveyed through a plating bath in accordance with an embodiment;

FIG. 6A is flowchart for the process of plating regions of a first major surface of a solar cell using an arrangement in accordance with an embodiment;

FIG. 6B is a flowchart of the variation of the arrangement illustrated in FIG. 6A which uses vacuum to ensure a uniform and intimate electrical contact between the back of the solar cell (second major surface) and the conductive portion of the cathode plate;

FIG. 7 is a photographic image of a surface of a solar cell plated using an arrangement in accordance with an embodiment; and

FIG. 8A and FIG. 8B are schematic illustrations showing different conveying arrangements for cathode plates in a plating bath in accordance with embodiments.

FIG. 9 is a cross-sectional representation of an edge region of a substrate sealed to a support structure in accordance with one or more embodiments.

FIG. 10 is a cross-sectional representation of an edge region of a substrate in accordance with one or more embodiments.

### DETAILED DESCRIPTION OF EMBODIMENTS

Embodiments of the present disclosure relate to a method for depositing a metallic material on a surface of a substrate, such as a silicon-based substrate including a solar cell, by electrodepositing the metallic material using a solution of metal ions. The metallic material is typically deposited such that an electrode pattern is formed on the surface of the substrate. The electrode pattern provides electrical contact to and/or from the substrate.

In one embodiment the metallic material forming the contact pattern includes copper. However, in variations of the described embodiment the contact pattern may also include other metals such as copper alloys, nickel and nickel alloys, tin and tin alloys and silver. When the substrate is a solar cell, the pattern typically comprises a plurality of thin metal fingers, which are intercepted at right angles by one or more busbars. Depending on the design of a solar cell and, in particular, the lateral conductivity of the electrical carrier collection layers, the thin metal fingers can be spaced between 1.5 mm and 0.5 mm apart. The number of busbars per solar cell can be varied, though for larger wafer sizes the number of busbars is typically greater than 10. An important advantage of having a larger number of busbars is that the amount of metal that is required to form the metallic electrode pattern can be reduced as the area from which electrical current is collected is reduced. However, use of too many busbars results in increased shading of the solar cell. Hence an electrical optimization should be performed as is described in “Solar Cells: Operating Principles, Technology and System Applications (The Red Book)” by M. Green (ISBN: 0858235803).

The electroplated metallic contact pattern can be formed on just one major surface of the substrate, or on both major surfaces of a substrate. The latter arrangement is advantageous in solar cell applications because it allows the metallised solar cells to be interconnected into bifacial modules, which can receive light from both major surfaces. Bifaciality is especially advantageous in ground-mounted PV installations where highly reflective backgrounds can result in larger electricity generation over a period of time.

The term “electroplating” is used throughout this specification to refer to the general process of electrodeposition of a material onto a surface.

The more terms “light-induced plating” and “light-induced electroplating” are used throughout this specification to refer to an electroplating process in which a substrate absorbs light and generates an electrical current which is used to electrodeposit a metallic material on n-type surface regions of the substrate. Typically, a cathodic bias current is applied to the p-type substrate surface to allow the plating rate to be more readily controlled.

The terms “forward-biased plating” or “forward-biased electroplating” are used throughout this specification to refer to a process of electroplating p-type regions of a substrate. In this process a cathodic current is induced at the p-type regions of the substrate to electrodeposit a metallic material on those regions by applying a cathodic current to the n-type cell surface to forward bias the semiconductor junction of the substrate.

In order to electroplate a metallic electrode pattern on a substrate surface, a pattern of openings must first be formed through a masking layer to allow the plating electrolyte to contact the electrically conductive regions of the substrate only where the metallic contact pattern is required. The masking material may include an inorganic material such as SiO₂ or SiNₓ or an organic material, such as a resin polymer or hotmelt ink. Patterning of this masking material can be formed using photolithography, a laser or a printer, such as an inkjet printer.

Forming a pattern of openings in a resin polymer layer is described for example in: Z. Li et al., Patterned masking using polymers: insights and developments from silicon photovoltaics, International Material Reviews, 61:6, 416-435, 2016). Another polymer masking method comprises the direct printing of a hot melt wax mask. For this method, the wax is melted in the printhead and, when encountering the substrate, the wax solidifies in a mask pattern (for further details refer to: A. Descoeudres et al., Low-temperature processes for passivation and metallization of high-efficiency crystalline silicon solar cells, Solar Energy, 175, 54, 2018).

Alternatively, a thin inorganic mask can be used with patterning being achieved using laser ablation or inkjet removal of the inorganic material in the pattern of the desired metallic grid (for further details refer to T. Hatt et al., Advances with resist-free copper plating approaches for the metallization of silicon heterojunction solar cells, AIP Conference Proceedings 2156, 020010, 2019). In practice any of these masking/patterning methods can be used for one or more embodiments of the present disclosure.

FIG. 10 shows a cross-sectional view of an arrangement in accordance with an embodiment. The arrangement includes a substrate 12 having a first major surface 14 and a second major surface 16. The substrate 12 is shown in FIG. 10 as having a masking material 26. There is also an arrangement 18 for depositing a metallic material on a surface of the substrate 12. The arrangement 18 has a support structure 20 and an electrode 22. The electrode 22 is depicted generally in FIG. 10 and can be embodied in different forms. For example, the electrode 22 may include a conductive plate which contacts the second major surface 16 and/or a lead or contact that contacts the substrate 12 or the first major surface 16. If the electrode 22 contacts the first major surface 14, a conductive layer may be deposited onto the substrate 12 to form part of the first major surface 14. In use, the support structure 20 supports the second major surface 16 of the substrate 12 and the electrode 22 contacts the substrate 12. To plate the first major surface 14 with a metal, the substrate 12 and counter electrode (not shown in FIG. 10) is contacted with an electrolyte and then a current is passed from the counter electrode, through the electrolyte and to the first major surface 14. Contacting the substrate 12 and counter electrode with the electrolyte may include partially or fully immersing the substrate 12 in the electrolyte solution. In an embodiment, a seal 24 is provided around a perimeter of the substrate 12. The seal 24 helps prevent ingress of fluid such as the electrolyte between the second major surface 16 and the support structure 20.

More specific embodiments will now be described with reference to the figures to form an electrical contact on a solar cell as an example of a substrate. However, the disclosure is not limited to solar cells, and other substrates may be used in place of solar cells without departing from the scope of the disclosure. Examples of substrates that can be used in one or more embodiments include those that are organic, ceramic, glass, silicon or metal based used, and that are used in the electronic or semiconductor industries.

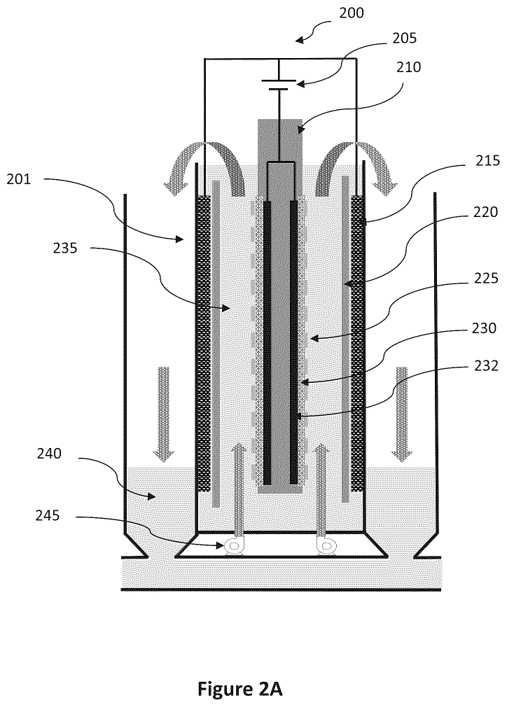

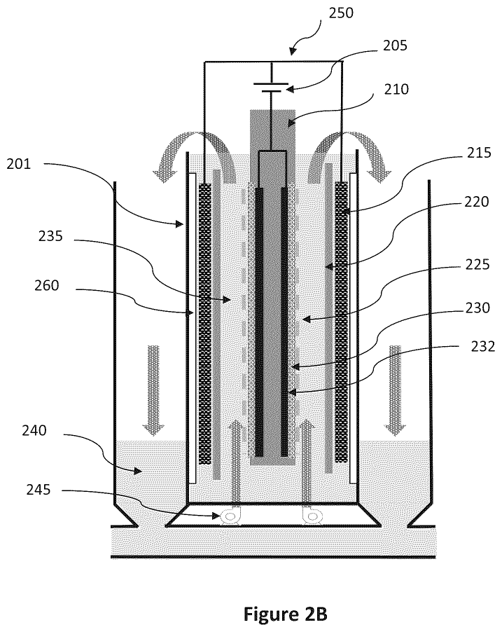

FIG. 2A shows a cross-sectional view of an arrangement in accordance with an embodiment for the case of forward-biased plating of metal (e.g., copper) on one or more exposed conductive regions of a first major surface of a substrate, which in the Figures is shown as described as being solar cells 230. However, as mentioned, the solar cells 230 are exemplary only. The solar cells 230 are positioned on opposite major surfaces of a support structure which in FIG. 2A is shown as planar cathode plate 210 (i.e. an electrode structure) and the first major surface of each of the solar cells 230 is covered with a masking material 225 which exposes the solar cell regions to be electroplated. Optionally, the cathode plates 210 can be configured to carry a single solar cell 230. In this variation to FIG. 2A, the plating arrangement 200 can be simplified to be effectively half of the depicted arrangement.

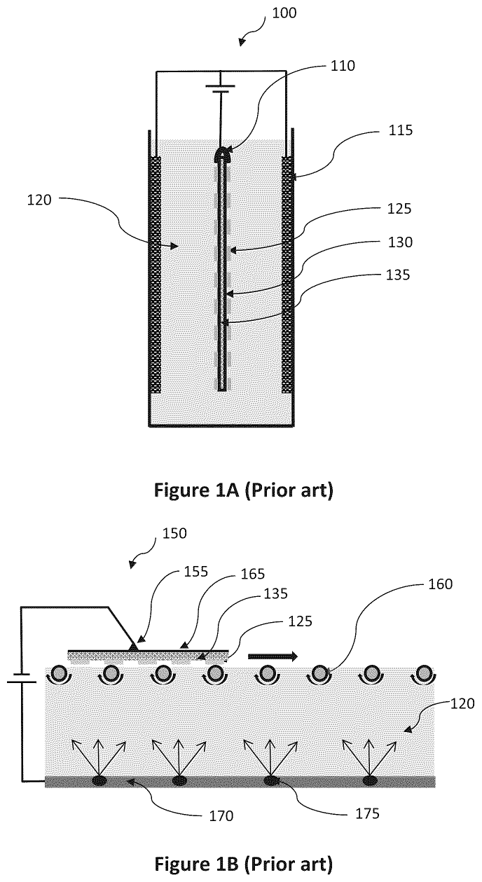

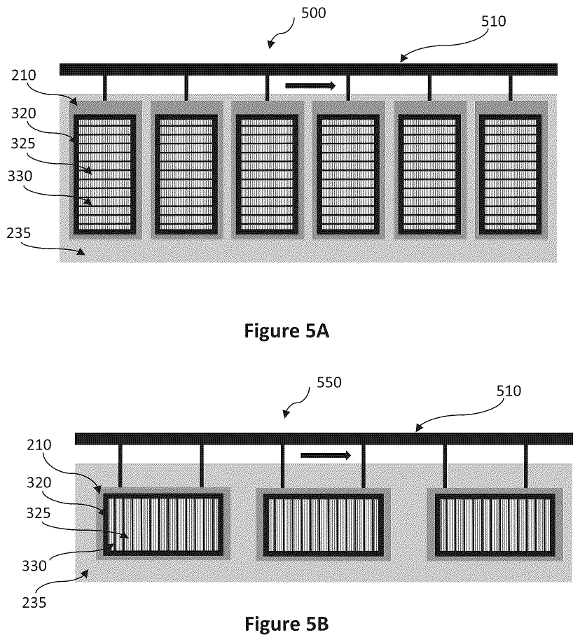

The solar cells 230 are held in a vertical orientation in the plating arrangement 200. However, distinct from the prior art arrangement shown in FIG. 1A, is that each solar cell 230 is held at the cathode plate 210 while being electroplated. The cathode plate 210 with solar cells 230 can optionally be conveyed through a plating bath 201 as shown schematically in FIG. 5A and FIG. 5B, with the cathode plates 210 being conveyed in either portrait or landscape configuration (if the width and height of the solar cell wafers differ).

Electrical current for electroplating of the exposed surface portions of the solar cells 230 is in this embodiment provided by a power source 205, the negative terminal of which is electrically connected to an electrode which is in the form of a planar conductive plate 232 sealed within the cathode plate 210 which is in physical contact with a second major surface of the solar cell 230. So, for example, if a metallic electrode pattern on the ‘front’ surface of a solar cell 230 is being formed, then the conductive plate 232 is in physical contact with the rear surface of the solar cell 230 as shown in FIG. 2A. Therefore, the second major surface of the solar cells 230 are attached to the electrically conductive surface portion of the cathode plate 210. The electrically conductive surface portion of the cathode plate 210 is in direct or indirect electrical contact with, and supports, the solar cells 230. The conductive plate 232 can be formed from a metal such as copper, nickel, or an alloy such as steel. Steel 316 is a particularly advantageous electrode material because it has a higher resistance to pitting and crevice corrosion in chloride environments. Chloride ions are frequently used in copper plating electrolytes to both assist in sacrificial anode corrosion and enhance the rate of copper deposition through facilitating interaction with commonly used additives.

The conductive plate 232 may also be formed from graphite and in particular high purity, low porosity pyrolytic graphite (which limits the shedding of carbon particles into the plating electrolyte 235 in the event that the conductive plate 232 is wet by electrolyte) or silicon carbide. An advantage of forming the conductive plate 232 from graphite is that elastic modulus of graphite is typically <50 GPa, where harder electrode materials such as stainless steel can have elastic moduli exceeding 200 GPa. A more elastic, or compressible, conductive plate material is beneficial in that it is more compatible with the larger and thin wafers which are typically used for solar cell fabrication. Elasticity in the conductive plate material is most beneficial if a vacuum is used to either load the solar cells 230 onto the cathode plate 210 or assist in holding the solar cells to the cathode plate during the plating process.

Other compressible conductive materials that can be used are conductive polymeric foams, such as polyurethane foams which contain metal or carbon components that impart conductivity. Both the graphite and polymeric foams have an additional benefit in that they may be readily engineered to allow a vacuum to pass through the bulk material to hold the solar cell 230 to the cathode plate 210. These materials can also have their surface modified to prevent the passage of fluids such as the electroplating electrolytes.

In one embodiment the surfaces of the cathode plate 210, apart from the conductive plate 232, are formed from an insulating (non-conducting) material such polypropylene (PP), however alternative materials such as polyvinyl chloride (PVC), polyethylene (PE), polytetrafluorethylene (PTFE), polyethylene terephthalate (PET), polysulfone (PSU), perfluoroalkoxy alkane (PFA), polycarbonates (PC), polyvinylidene fluoride (PVDF), polyaryletherketone (PAEK) such as polyether ether ketone (PEEK), polyetherimide (PEI), polyamides such as Nylon, polyimides such as Kapton, polyoxymethylenes such as Delrin, polyphenylene oxides (PPO) and polyphenylene ether (PPE) blends such as Noryl, or polyurethanes can also be used.

The cathode plate 210 can also be formed from a conductive material, such as the material(s) used for the conductive plate 232, with those regions of the cathode plate 210 other than the conductive plate 232 being insulated due to be being anodized, oxidized by other means or coated with an insulating material, such as Teflon. In the latter variation, a thick and non-porous coating should be applied in order to avoid the formation of shunting pathways.

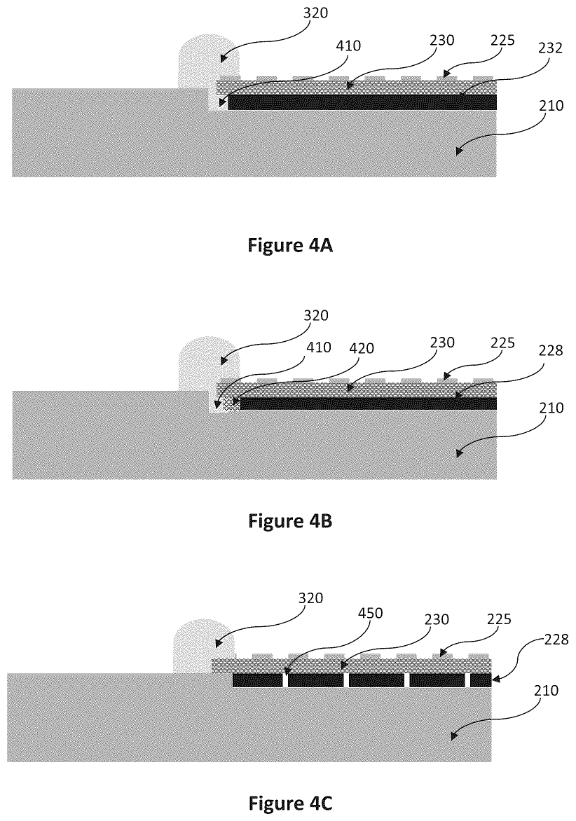

In one specific embodiment, conductive plates 232 are positioned on the surface of the cathode plate 210 as schematically shown in FIGS. 2A, 2B and FIG. 4. The arrangement of the conductive plate 232 on the cathode plate 210 is described in more detail with respect to FIGS. 4A, 4B and 4C.

In the case of forward-biased plating, the applied power supply acts to forward bias the solar cell's semiconductor p-n junction and allows current to flow through the solar cell 230 from the conductive plate 232 of the cathode plate 210 via the n-type (second major) surface towards the p-type surface regions of the solar cells 230 in a direction which is perpendicular to the major solar cell surfaces. The p-type regions of the solar cells 230, exposed to the plating electrolyte 235 through the openings in the masking material, become cathodic inducing the reduction of metal (e.g., copper) ions in the plating electrolyte to metal on the exposed solar cell 230 surfaces.

Since, the cathode plate 210 carries in this embodiment solar cells 230 on both of its major surfaces, the arrangement 200 is constructed in an embodiment with two counter electrodes in the form of anodes 215 as shown in FIG. 2A. For both the solar cells 230 on the cathode plate, the p-type surface portions are in physical contact with the plating electrolyte 235 through openings in their respective masking material 225. Arrangement 200 has a bath or plating bath 201 and the anodes 215 are positioned in the plating bath 201 such as towards or at a side of the bath.

In one embodiment insoluble anodes comprising titanium meshes with mixed metal oxide (MMO) coatings are used to enable electroplating at high current densities (i.e., >40 mA/cm² and more preferably at rates of ≥100 mA/cm²) by evolving gas (O₂ or Cl₂) at the anode. These MMO coatings can comprise one or more metal oxides, such as titanium oxide, tantalum oxide, ruthenium oxide and iridium oxide. Other insoluble anodes, such as platinized titanium, titanium oxide or tantalum oxide may also be used. Further, soluble anodes comprising phosphorus-doped copper may also be used, though at a slightly reduced plating current density of up to ˜40 mA/cm².

The anode meshes are positioned in the plating electrolyte 235 at a distance of between 1 and 10 cm from the surfaces of the solar cells 230 on the cathode plates 210, and more specifically between 1 and 5 cm away from the solar cell 230 surfaces. In alternative variations, the anodes may be in the form of bars, rods or pellets, providing that the anode to cathode surface area ratio exceeds 1.5.

Anode shields 220 are positioned close to each of the anodes 215 to guide the flow of any generated gas bubbles upward and reduce the flow of additives towards the anode. Oxygen generated from inert anodes is known to increase the rate at which additives, such as brighteners can degrade.

The anode shields 220 are in this embodiment formed from polypropylene, though other polymeric materials such as acrylic resins, chlorinated polyvinyl chloride, polyethylene, polypropylene, polyvinyl chloride and polyvinylidene chloride can also be used. The anode shields 220 can alternatively be deployed as shielding bags which enclose all surfaces of the anode, except the top surface.

To ensure that there is a sufficient flow of metal ions across the solar cell surfaces to support fast electroplating rates, eductors or other fluid flow conditioners 245 are employed at the bottom of the tank. In this embodiment the plating electrolyte flows substantially upwardly over the solar cell 230 surface and into the side reservoirs 240 of the plating electrolyte 235 at a linear flow rate between 50 mm/min and 5000 mm/min, or between 500 mm/min and 1500 mm/min. These linear flow rates correspond to material flow rates of 3-5 metric tons per hour of plating electrolyte across the surface of the solar cell 230.

Plating electrolyte 235 collected via the side reservoirs 240 is passed back, via a series of carbon or polypropylene filters, into the main plating electrolyte reservoir, where it is routinely monitored and dosed with the metal source (i.e., copper source). For example, for copper plating, CuO(s) can be added to the plating electrolyte reservoir to maintain the copper (II) ion concentration between 20 and 50 g/L, and or for fast plating at least at 50 g/L.

Although FIGS. 2A and 2B show eductors or flow conditioners 245 which direct electrolyte flow in a vertical direction, flow can also be introduced from directions other than vertical, providing that such flows having a vertical vector component. In other variations, the plating electrolyte 235 can be first pumped to the top of the plating bath 200 and then directed downwards over the solar cell 230 surface, with plating electrolyte replacement over the solar cell surface occurring due to gravity.

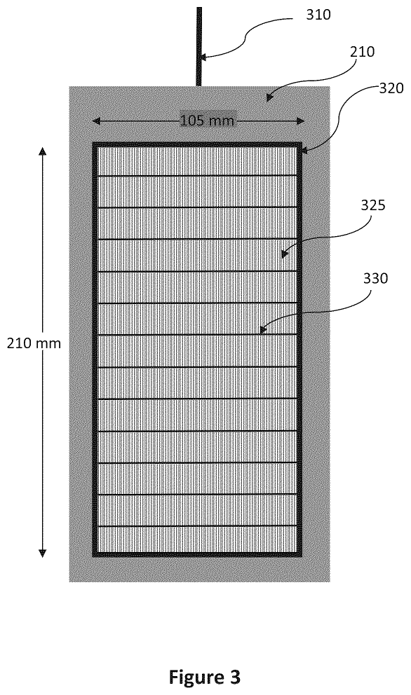

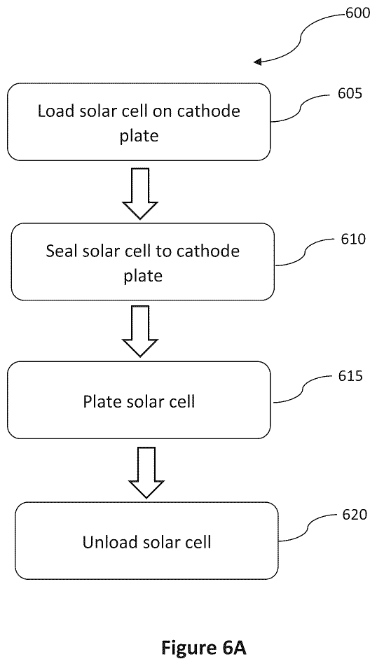

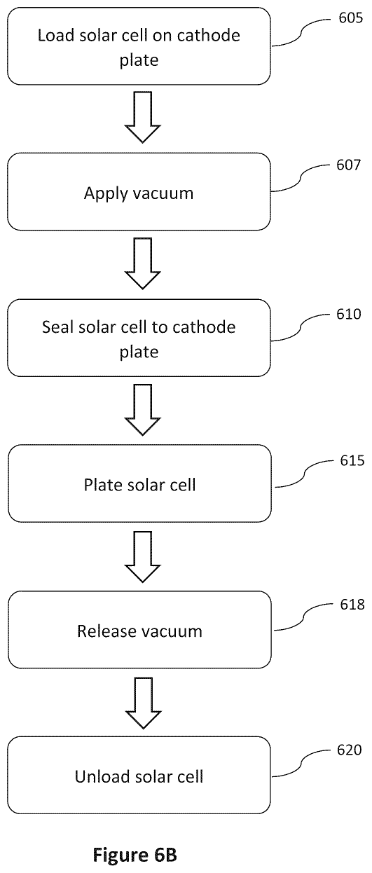

The solar cells 230 are held to the cathode plate 210 with a sealing rim 320 as shown in more detail in FIG. 3. The sealing rim 320 surrounds the solar cells 230. The method of forming this sealing rim 320 is discussed below in more detail with respect to the flowcharts in FIG. 6A and FIG. 6B. Also shown in FIG. 3 is the pattern of openings typically used for a solar cell with dimensions of 210 mm×105 mm (or half-cut M12 wafer). This metallic electrode pattern comprises a plurality of narrow fingers 325 and a plurality of wider busbars 330. The opening width of the fingers may be between 5 and 30 mm, or between 5 and 15 mm. The busbars 330 can alternatively comprise a series of solder pad regions connected by narrower linear regions to minimize surface shading whilst allowing for the metallised solar cells to be interconnected by soldering into laminated PV modules.

In the arrangement in accordance with an embodiment the portrait orientation cathode plates 210 are conveyed in a direction which is into the page in FIG. 2A as shown in FIG. 5A. Alternatively, the cathode plates 210 may be conveyed in a landscape orientation through a plating bath as schematically illustrated in FIG. 5B. The conveying of cathode plates 210 through a plating bath increases electrolyte flow over the solar cell 230 surface and averages effects arising from non-uniform electric field flux over the solar cell 230. In cases where a horizontal flow (due to solar cell conveying) is both preferable and sufficient for a particular plating arrangement, then the upward flow generated through the use of flow conditioners 245 can be omitted or provided at significantly lower flow rates.

FIG. 2B is a cross-sectional view of a plating bath arrangement 250 designed to perform light-induced plating of metal (e.g., copper) on exposed surface portions of a first major surface of solar cells 230, in this case the n-type surface. The arrangement 200 shown in FIG. 2A and the arrangement 250 shown in FIG. 2B are essentially the same, with the exception that the arrangement 250 includes units housing light sources 260. The light sources 260 are placed behind the anodes 215, however they can also be integrated with or placed either in front of or on the cathode side of the anode shield 220. In a further variation, the light source may be situated external to the electroplating tank and may shine through the walls of the electroplating bath, provided that the bath is constructed from a transparent material such as a transparent polymer or glass.

In the arrangement of the plating arrangement 200 and 250 as shown in FIG. 2A and FIG. 2B, the solar cells 230 and the anodes 215 are arranged in a manner such that a surface normal of the first major surface of the solar cells 230 are directed in a direction transversal to the direction of gravity.

Light from the light sources 260 induces a light-induced current in the solar cells 230 (disposed on each surface of the cathode plate), which induces the electrochemical deposition of metal at any n-type surface portions exposed to the plating electrolyte 235 through the openings in the masking material 225 on the solar cells 230.

The bias current from the power source 205 applied via the conductive plate 232 integrated on the cathode plate 210, and as described with reference to FIG. 2A, is delivered to the p-type surface (second major surface) of the solar cell 230 sealed to the cathode plate 210 and acts to reduce the resistance of the electrochemical circuit and ensure that the solar cells 230 operate closer to their short circuit current condition. This current also allows for tuning of the plating rate without requiring changes in the light sources 260.

The light sources 260 are in this embodiment light emitting diodes (LEDs), but alternatively other light sources such as incandescent lights, mercury or xenon arc-lamps or tungsten-halogen lamps, can also be used. The LED light sources are in this embodiment sealed in quartz or epoxy resin tubes which are arranged on the outside walls of the plating arrangement 250. The light source wavelength is selected such that the light can penetrate through the plating electrolyte 235 and masking material 225 coating the solar cell without significant loss of luminous power. For copper plating, a wavelength in the range from 400 to 700 nm, and more specifically between 450 and 550 nm may be used. However, white LEDs can also be used given their lower cost. The radiant flux of the light source 260 should be sufficient to ensure that a uniform light intensity of at least 0.1 sun is incident on the solar cell surface.

The same plating arrangement can be used to perform both forward bias plating (shown in FIG. 2A) and light induced plating (shown in FIG. 2B). For light-induced plating, solar cells 230 are mounted on the cathode plate 210 such that their n-type surface portions are exposed to the plating electrolyte 235, whereas for forward-biased plating the light sources are not used and the solar cells 230 are mounted on the cathode plate 210 such that the p-type surface portions are exposed to the plating electrolyte 235. The light source 260 can be configured such that it only operates during light-induced plating.

Although embodiments of the present disclosure are described below with reference to the formation of copper electrode patterns on silicon solar cells, it should be clear to a person skilled in the art that the method could also be applied to other solar cells, including thin film solar cells, such as solar cells comprising cadmium telluride (CdTe), copper indium gallium selenide (CIGS), perovskite structures and various tandem and multijunction devices.

The present disclosure will now be described in more detail with reference to the formation of electroplated copper electrode patterns on the surfaces of n-type silicon heterojunction (SHJ) solar cells, a type of silicon semiconducting solar cell, where doped amorphous (alternatively nano- or micro-crystalline) silicon layers are used to form each of the electron (n-type) and hole collectors (p-type) for the solar cell. Both major solar cell surfaces are coated with a transparent conducting oxide (TCO) which acts as an anti-reflection coating for the solar cell and facilitates lateral current flow to the metallic fingers of the contact grid.

Embodiments of the present disclosure can also be applied to other types of solar cells, such as other types of silicon-based solar cells, which may be fabricated on either n-type or p-type silicon wafers. In these alternative solar cells, doped silicon regions may form the electron and hole collectors, and the plated metallic electrodes can directly contact the doped silicon regions rather than a TCO.

The TCO of a SHJ solar cell may comprise indium tin oxide (ITO) with In₂O₃:SnO₂ ratios ranging from 90:10 to 97:3 or 99:1. Typically for higher light capture, the front surface of the solar cell will use a higher In₂O₃:SnO₂ ratio to reduce parasitic absorption. Alternatively, the TCO may comprise a range of alternative materials including but not limited to transition metal doped SnO₂, InWO, InCeO, InCsO, InTiO, InTaO and other indium free TCOs such as aluminum doped zinc oxide (AZO). Typically, the TCO thickness is in the range of 60 to 150 nm, such as between 70 and 100 nm. When a (metallised) SHJ cell is illuminated, electrons are collected in the n-type doped surface silicon layer (typically on the front surface) and then flow into the TCO where they are conducted laterally to reach the nearest metallic finger of the contact grid. Similarly, photo-generated holes are collected on the rear p-type silicon layer and flow via the TCO layer into the p-type (rear) contact grid.

The sheet resistance of the TCO is typically between 30 and 110 Ohm/sq, such as between 40 and 80 Ohm/sq. The finger spacing is optimized to minimize electrical losses which can arise from metal shading (resulting in reduced electrical current generation) and lateral resistance to current flow in the TCO layer.

An example of a method for forming an electroplated electrode pattern on the surface of a SHJ solar cell in accordance with an embodiment is now described with reference to FIG. 6A and FIG. 6B. For simplicity, the method is described for a single solar cell 230 mounted on a cathode plate 210. As shown in FIG. 2A and FIG. 2B, each cathode plate 210 may carry two separate solar cells 230 to increase the process throughput of the electroplating step. In a variation of the described embodiment, each cathode plate is arranged to carry even more than two solar cells, such as two or more solar cells per side.

At least the TCO surface of the solar cell 230 which is to be electroplated using the process flow summarized in FIG. 6A and FIG. 6B is coated with a masking layer with openings corresponding to the required electrode pattern. The masking layer may be formed in a manner analogous to that described above on page 19, line 13 to page 20, line 9 of this specification.

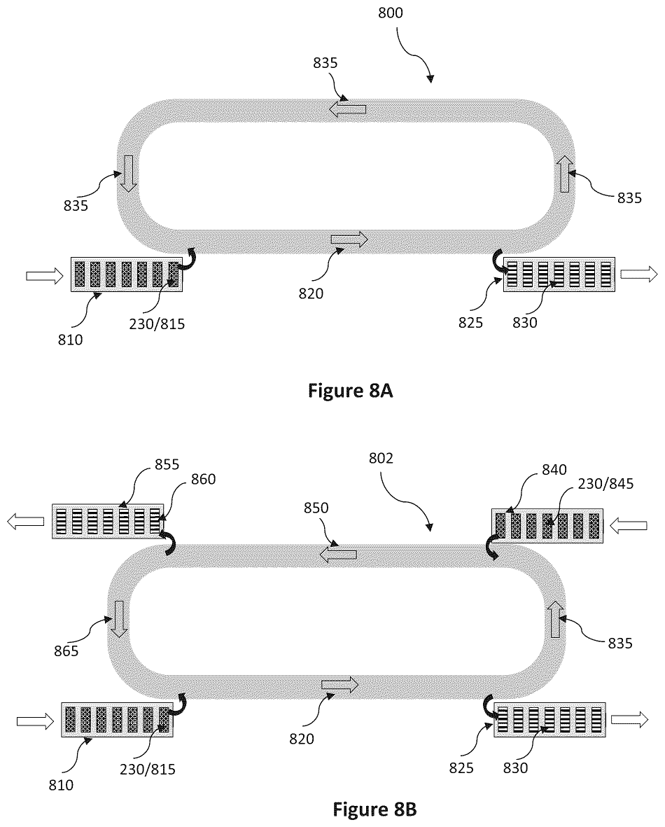

In step 605 of the method 600, the solar cell 230 with a masking layer is loaded on the cathode plate 210. If the cathode plate 210 is connected via a connector to an overhead rail or gantry for conveying purposes, as shown in FIG. 5A or FIG. 5B, then the cathode plate 210 is temporarily detached from the conveying gantry and guided or re-routed into a solar cell loading zone. This allows the velocity of the conveying gantry to be designed for the electroplating process and decoupled from the slower loading and unloading steps. Alternatively, the cathode plate 210 can be removed from the conveying gantry at the end of the electroplating process, allowing the loading of solar cells 230 to be completely decoupled from the conveying process used for electroplating in bath 201 for arrangement 200 or 250. Further variations of the conveying process will be discussed further below with reference to FIG. 8A and FIG. 8B.

The solar cell 230 is then sealed to the cathode plate 210 in step 610. A dispenser is used to deposit a heated material in the sealing rim 320 around the solar cell 230, which is schematically illustrated in FIG. 3 in front view and in FIG. 4 in cross-sectional view. The deposited material of the sealing rim 320 solidifies substantially on contact and holds the solar cell 230 to the cathode plate 210. It also prevents plating electrolyte 235 from penetrating behind the solar cell 230 and contacting its second major surface during the following wet chemical steps.

A vacuum can be applied to hold the rear (second major) surface of the solar cell 230 to the cathode plate 210 during the formation of the sealing rim 320. The vacuum can be applied via a series or array of vacuum openings engineered within the conductive plate 232 of the cathode plate 210. Alternatively, a negative pressure can be introduced between the second major surface of the solar cell 230 and the conductive plate 232, by temporarily heating the conductive plate 232.

The deposited material comprises or includes in one embodiment a phenolic resin with a softening point between 7° and 120° C., such as between 95 and 110° C. The resin is dispersed in a solvent comprising one or more of butyl acetate, dipropylene glycol methyl ether, diethylene glycol, ethyl acetate, ethyl lactate, ethylene glycol, glycerol, isopropanol, N-methylpyrrolidone, N, N-dimethylformamide, propylene glycol, propylene glycol methyl ether, propylene glycol methyl ether acetate, triethylene glycol.

The deposited material used to form the sealing rim 320 can includes a solution which includes a polymer and a weight fraction of the polymer in the solution is between 60 and 95% by weight, such as between 75 and 85% by weight.

A tackifier, such as commonly used terpenes, rosins, rosin esters and anhydride rosin esters may be added to the mixture comprising the polymeric material to improve the adhesion of the dispensed material to both the cathode plate 210 and solar cell 230. The % (w/v) of the resin is in the solution is in one embodiment between 65 and 95% and depends on the solvent(s) used.

Other polymeric materials, such as polyesters, polyethylene, polypropylene, polycarbonate, polyurethane, polyvinyl chloride and blends and co-polymers of these polymers, with appropriate solvents, can also be used without departing from the scope of embodiments of the present disclosure. In further variations, commercially available hot melt adhesives (glues) can also be used. These glues typically comprise a polymeric base material (such as ethylene vinyl acetate co-polymers, polyolefins, polyesters, polyamides and polyurethanes), tackifiers (such as terpenes, rosins and resins) to improve adhesion, waxes to increase the setting rate and improve bond strength, plasticisers (such as benzoates, paraffin and phthalates) and fillers (such as silicate, calcium carbonate). Hot melt adhesives are typically provided as solids which are subsequently melted in a glue dispenser.

The components of the deposited material can be tuned for different seal widths and different manufacturing temperatures and humidities. If a particularly resistant thermoset seal is required, a cross-linking agent can be added to a polymer composition in the deposited material. For example, for a phenolic resin, hexamethylenetetramine (HMTA) can be added at a concentration of 8 to 12% (w/w) such as ˜ 10% (w/w). On heating the polymer mixture above the polymer's curing temperature, the polymer chains become cross-linked. Hence a curing step is performed after the polymeric mixture has been deposited on the cathode plate 210. A thermoset seal cannot be removed by softening and consequently is typically only used when a plating step is performed at a temperature at or above the softening temperature of the polymer material.

Polymeric material can be added to the dispenser reservoir either as solid (e.g., pre-prepared pellets or balls) or as a pre-prepared liquid. The liquid can be transferred to the reservoir at a temperature which is higher than room temperature or at substantially room temperature. The reservoir of the dispenser heats and maintains the polymeric material at the dispensing temperature. In variations where a solvent in the polymer material has a high vapour pressure, the dispenser reservoir can facilitate venting of vapour which is volatized during the heating process.

In a further variation, the deposited material can comprise a monomer which is subsequently polymerized on the cathode plate 210 surface. Monomers such as methyl methacrylate can be polymerized at low temperatures using redox initiators such as Fenton's reagent, metallic catalysts and emulsion gels comprising surfactants such as cetyltrimethylammonium bromide. These polymerization initiators can be added to the deposited material from a second reservoir shortly before deposition, in which case, if the deposited material is heated, then polymerization can commence during deposition resulting in reduced spreading of the deposited material on contact with the cathode plate surface and consequently a narrower sealing rim 320.

Alternatively, the polymerization initiator can be deposited using a second dispensing unit which either precedes or follows the dispensing of the monomer on the cathode plate 210 surface. Surfactants can be added to each or one of the monomer and/or initiator solutions to ensure that a continuous sealing rim 320 forms on polymerization and solidification of the deposited materials.

The benefit of forming the seal by in-situ polymerization of monomers is that the mass of material deposited for the sealing rim 320 can be reduced thus reducing the cost of forming the seal. The deposition of less viscous materials can also present benefits in seal formation for cathode plates utilizing the structures depicted in FIGS. 4A and 4B, which are described below, as the less viscous materials can flow more readily into the groove structures in the cathode plate 210.

In one embodiment, the cathode plate 210 is engineered such that the conductive plate 232 is recessed into the cathode plate 210 with a groove in the form of small gap 410 at all edges as shown in FIG. 4A. The gap 410 is provided in an embodiment with an extension that undercuts the edge portion of the solar cells 320. The width of the gap 410 is between 1 and 10 mm such as between 2 and 5 mm and the depth of the recess into the cathode plate 210 at the gap region 410 is at least 2 mm such as 4-5 mm. When the polymer material is deposited around the perimeter of the solar cell 230, some of the material flows into the gap 410 and hardens to form an interlocking structure which improves the sealing performance of the sealing rim 320.

FIG. 4B shows a further variation where a thin additional gasket 420 is positioned between the gap 410 and the conductive plate 228. The gasket 420 serves as a secondary seal, in the event that the sealing rim 320 fails. The gasket 420 is in one embodiment composed of graphite or a material which has a similar elastic modulus as the material used for the conductive plate 232. Other materials, such as rubber including silicone rubber, Teflon and Viton can also be used for the gasket 420. The gasket material is in one embodiment resistant to corrosion by any of the plating electrolytes used for the electroplating process.

A particular advantage of using an electrically conductive material for the gasket 420, such as graphite, is that electrical current is more effectively delivered to the edge regions of the solar cell 230. The plated grid pattern to be formed on the front surface of the solar cell 230 may extend to within 1 mm from the edge of the solar cell wafer and, more commonly, between 1 and 2 mm from the edge of the solar cell wafer. Delivering electrical current as close as possible to this edge region of the solar cell 230 can ensure that edge structures, such as metallic fingers and busbars, are plated to approximately the same height as fingers and busbars located in the centre of the solar cell 230.

A further variation of the cathode plate 210 is shown in FIG. 4C. In this variation, the solar cell 230 is held flush with the surface of the cathode plate 210 and not recessed into the plate as shown for FIGS. 4A and 4B. In this variation the sealing rim 320 contacts the first major surface of the solar cell 230 and the cathode plate 210 surface. Also shown in FIG. 4C are a series of vacuum lines 450 machined into and contained within the conductive plate 228 of the cathode plate 210. As mentioned above, a vacuum can be applied before the sealing rim 320 is formed and optionally retained during the plating process.

The width of the sealing rim 320 may be between 1 and 5 mm such as between 1 and 3 mm. The sealing rim 320 extends over the entire perimeter of the solar cell 230 and the adjacent regions of the cathode plate 210. In addition to holding the solar cell 230 to the cathode plate 210, the sealing rim 320 also acts to prevent the plating electrolyte 235 from contacting the edge regions of the solar cell 230 where it can cause plating to the edges. Such plating can degrade solar cell electrical performance and impact PV module durability. The ability to prevent plating to wafer edges presents a further advantage of methods in accordance with an embodiment of the present disclosure compared with the prior art plating methods.

The polymer material for the sealing rim 320 is dispensed at a temperature between 7° and 100° C., such as between 8° and 100° C. The polymeric material begins to solidify immediately on contact with the cathode plate 210 and, once hardened, the vacuum line is disconnected before the cathode plate 210 is re-connected to the gantry for conveying. Alternatively, for increased process control, the vacuum can be maintained whilst the solar cells 230 are conveyed through and plated in the arrangement 200 or 250.

The solar cell 230 mounted on the cathode plate 210 is then plated in step 615 to form a metallic electrode pattern on the first major surface of the solar cell 230. For some TCO surfaces, it is necessary to first electroplate a nickel seed layer for improved durability. The nickel seed layer can be electroplated using light-induced plating (n-type) and forward-biased plating (p-type) from proprietary nickel-plating solutions, such Watts Nickel or Barret SN1 recipes. The thickness of the nickel seed layer is between 0.5 mm and 2 mm, such as ˜1 mm. The plating process is substantially the same as used to plate copper, which will be described below.

Copper is then plated onto either the nickel seed layer surface (if it is being used) or a clean TCO surface. One or more embodiments of the present disclosure do not require a specific copper electroplating chemistry to be used. The most-commonly used copper chemistry used for solar cell metallization is a CuSO₄/H₂SO₄ plating electrolyte with proprietary suppressor, accelerator and leveler additives. Sulphuric acid-based copper plating electrolytes can be commercially sourced from many suppliers, including Technic, Inc. (USA) and MKS/Atotech (Europe). Alternatively, copper plating electrolytes comprising nitric acid can also be used (see, for example, TWI490376). Use of insoluble anodes, as discussed earlier, allows plating current densities exceeding 40 mA/cm² to be used.

Embodiments of the present disclosure may offer the ability to plate the copper electrode in as short a time as possible, which addresses a key limitation of solar cell electroplating equipment in accordance with the prior art. Currently used solar cell manufacturing equipment enables a throughput for other process steps in a solar cell's fabrication in excess of 10,000 wafers per hour. By reducing the time required to electroplate a metallic electrode on a solar cell from presently ˜8 to ˜3 min per solar cell using the method in accordance with one or more embodiments of the present disclosure, the work-in-progress product time is more than halved, which reduces the factory footprint significantly.

Copper plated electrodes are capped with a metal such as silver or tin to prevent copper oxidation and to allow the solar cells to be interconnected using solder-coated wires. The silver or tin capping layers are usually ˜ 1 mm thick and can be applied using light-induced plating and/or forward biased plating whilst the solar cell is mounted on the cathode plate 210 and as described above, or via a contactless immersion (also called a displacement) process formed at a later stage. Use of an immersion process for the capping metal, typically results in capping layers with a thickness of <1 mm.

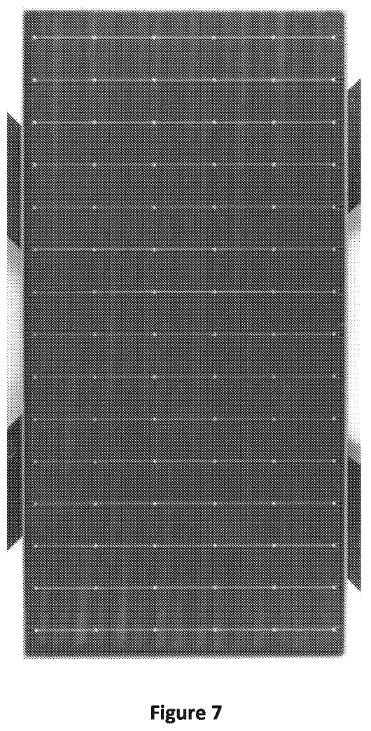

FIG. 7 shows the surface of a solar cell 230, fabricated on a half-cut M12 wafer (210 mm×105 mm), which has been metallised with copper using the method 600. The solar cell 230 employs busbars with solder pads to allow solar cells to be interconnected by soldering of wires to the solder pads on the solar cell surface.

Once the plating steps have been completed, the solar cell 230 is unloaded from the cathode plate 210. For a seal material comprising a thermoplastic polymer, heat can be locally applied to soften the sealing rim 320 whilst the solar cell 230 is supported by a gripping unit. The solar cell 230 is then removed from the cathode plate 210 by the gripping unit and moved to the next step in the solar cell manufacturing process. The polymeric residue remaining on the cathode plate 210 is then removed by spraying a solvent through a series of jets, such as ultrasonic jets. The cleaning solvent may include a mixture of approximately equal proportions of methyl ethyl ketone (MEK) and isopropyl alcohol (IPA), though other solvents and solvent mixes can also be used to ensure that residue is removed completely. The cleaned cathode plate is then rinsed in a further solvent such as acetone or IPA, or a mixture of other high vapour pressure solvents, to ensure a clean and dry cathode plate 210 for the next solar cell 230 to be loaded.

An arrangement of the cathode plate conveying system 800 in accordance with an embodiment is schematically illustrated in FIG. 8A. The arrangement allows the loaded cathode plates 210 to pass through plating bath 201 for arrangement 200 and/or 250 whilst connected to an overhead transport rail or gantry.

An incoming belt 810 supplies masked solar cells 230 to a loading station which loads the solar cells onto individual cathode plates 210 using the method described with reference to FIG. 6A and FIG. 6B. The loaded cathode plates then move through the plating bath 201 for arrangement 200 or arrangement 250 in a plating process (forward biased plating/light-induced plating) 820. On completion of the plating process, the plated solar cells 830 are removed and positioned on an exit belt 825, from where they are conveyed to the post plating steps (e.g., removing the masking material from the surface). The cathode plates 210 are then cleaned and dried during the return of the conveying system (in process 835 of FIG. 8A).

In an alternative arrangement, the cathode plates with plated solar cells may be removed from the conveying gantry after process 820 and process 835 and subsequent loading of the cathode plates 210 with solar cells 230 can be performed in a separate process from the conveying arrangement depicted in FIG. 8A. With this arrangement the incoming belt 810 would carry cathode plates 210 already reloaded with solar cell(s) 815 and the loaded cathode plates would be re-connected to the conveying gantry.

FIG. 8B illustrates a further alternative conveying arrangement 802 where the cleaning and drying of the cathode plates 210 (i.e., process 835) is performed after plating process 820 at the turning end of the conveying line. This leaves the clean cathode plates 210 able to be reloaded with masked solar cells 230 from a second incoming belt 840 to perform a second plating process 850 during the return of the conveying system.

Alternatively, cathodes plates 210 with plated solar cells can be removed from the conveying gantry after process 820. In a separate series of processes which are external to the conveying gantry, the plated solar cells 830 are removed and placed on the exit belt 825, then the cathode plate 210 is cleaned, dried and reloaded with solar cells. Incoming belt 840 would, for this arrangement, be carrying cathode plates already loaded with solar cell(s) 845 in preparation for process 850.

One of the plating processes 820 and 850 is a light induced plating process of the n-type surfaces of the solar cells and the other is forward-biased plating of the p-type solar cells. The arrangement of FIG. 8B is particularly advantageous from a factory layout perspective in that the solar cell processing throughput is doubled with very little additional equipment footprint.

For each of the conveying arrangements 800 and 802, optionally a two-speed conveying gantry is employed to ensure sufficient time for the loading and unloading steps without compromising on the speed of the conveyor during process 820 and 850. As cathode plates approach the unloading step, they are transferred to the lower speed conveyor, which is decoupled from the main conveyor used for processes 820 and 850, via a connector rail. Whilst being transported at the slower speed all loading, unloading and cleaning/drying steps can be performed at a safe slower speed. Once cathode plates have been reloaded, they are then transferred back to the main conveyor unit via a further connector rail in preparation for processes 820 or 850.

As already mentioned, embodiments of the disclosure have been described with reference to a solar cell as an exemplary substrate, but the disclosure is not limited to solar cell substrate and that the substrate may include those that are organic, ceramic, glass, silicon or metal based used in the electronic or semiconductor industries. The plating of the solar cell has also been described as being performed with the solar cell (i.e. the substrate) being in a vertical orientation. However, the disclosure is not limited to such orientations, and the substrate can be plated when in a vertical or horizontal orientation. For example, the at least one substrate may be contacted with the electrolyte in a manner such that: the first major surface of the at least one substrate is oriented in a vertical orientation and substantially along the direction of gravity; or the first major surface of the at least one substrate is oriented in a direction transversal to the direction of gravity.

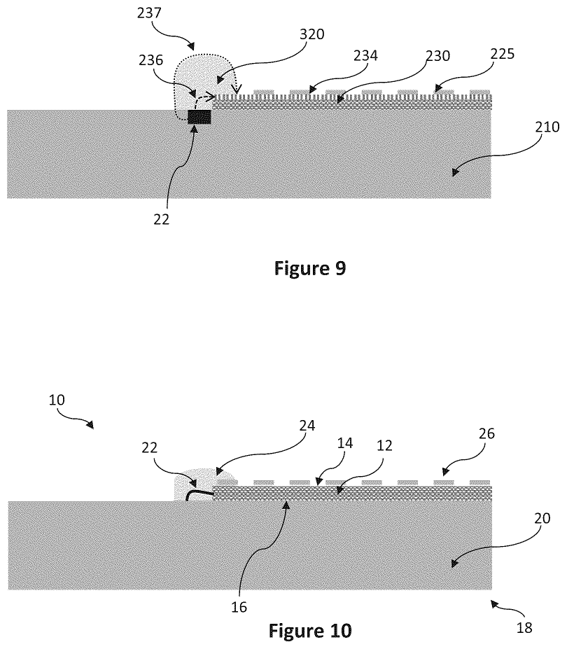

The embodiments related to substrate being a solar cell have been described as passing a current through the substrate 230 to achieve electroplating on the surface of the substrate 230. However, depending on the type of substrate, this type of current flow is not always required and in some embodiments the electroplating process directs a current to the surface to be plated rather than through the substrate. With reference to FIG. 9, in an embodiment, the substrate 230 is provided with a conductive seed layer 234 and the masking material 225 (if required) is applied on top of the conductive seed layer 234. In an embodiment, the sealing rim 320 is formed from and/or contains a conductive material or structure that is in contact with the electrode 22. Such an arrangement allows current to flow from the electrode 22, through the sealing rim 320 and into the conductive seed layer 234, as shown schematically by arrow 236, thereby allowing electroplating on the exposed surfaces of the conductive seed layer 234. In an embodiment, the sealing rim 320 may be provided with a conductive contact that extends from the electrode 22 and contacts the conductive seed layer 234. In an embodiment, the outer surface of the sealing rim 320 is provided with a conductive material or structure to allow current to flow around the sealing rim 320, as shown by arrow 237. Accordingly, for embodiments that require current to flow around the substrate (i.e. from the electrode 22 to the conductive seed layer 234) current may pass through or around the sealing rim 320.

The sealing rim 320 is also shown as covering or encapsulating the entire edge surface of the substrate 230 including the conductive seed layer 234. However, this depiction is exemplary only, and in some embodiments the sealing rim 320 only forms a seal with a portion of a side of the substrate 230. In such embodiments, an edge of the conductive seed layer 234 may be exposed. When the edge of the conductive seed layer 234 is exposed, a conductive connecting structure may be used to electrically connect the conductive seed layer 234 to the conductive seed layer 234.

The form of the conductive seed layer 234 can vary and be formed in numerous ways, for example by various vapor deposition techniques, and typically has a thickness in the order of 10 nm to 500 nm. The form of the electrode 22 as shown in FIG. 9 is also exemplary only and can vary depending on the plating application and form of the substrate. For example, the electrode 22 may only be positioned near a perimeter of the substrate 230. Accordingly, the physical form of the electrode 22 can vary so long as it allows for either direct or indirect electrical contact with the substrate 230 to allow current to either flow through the substrate 230 or around the substrate 230 e.g. to the conductive seed layer 234.

Throughout this specification the term “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

1. A method for depositing a metallic material on a surface of at least one substrate, the method comprising the steps of:
providing the at least one substrate having opposite first and second major surfaces;
providing an arrangement for depositing a metallic material on a surface of the at least one substrate, the arrangement comprising: a support structure having an electrode, a counter electrode, and an electrolyte suitable for depositing metal ions onto one or more portions of the first major surface of the at least one substrate;
attaching the at least one substrate to the support structure such that the electrode is in electrical contact with the at least one substrate;
contacting the at least one substrate and the counter electrode with the electrolyte; and thereafter
passing an electrical current through the electrolyte between the first major surface of the at least one substrate and the counter electrode such that the metallic material is deposited at at least some areas of the first major surface of the at least one substrate.

2. The method of claim 1, wherein the at least one substrate is contacted with the electrolyte in a manner such that:
the first major surface of the at least one substrate is oriented in a vertical orientation and substantially along the direction of gravity; or
the first major surface of the at least one substrate is oriented in a direction transversal to the direction of gravity.

3. The method of claim 1, wherein the arrangement comprises a voltage source and wherein a magnitude of the electrical current passing through the electrolyte between the electrode and the counter electrode is determined by the voltage source.

4. The method of claim 3, wherein the electrode is electrically coupled to a negative terminal of the voltage source and the counter electrode is electrically coupled to a positive terminal of the voltage source.

5. The method of claim 4, wherein the counter electrode is a soluble electrode and provides a source of metal ions for the metal deposition on the one or more portions of the first major surface of the at least one substrate.

6. The method of claim 4, wherein the counter electrode is an insoluble electrode.

7. The method of claim 6, wherein the surface of the counter electrode is coated with a metal oxide or combination of metal oxides such as titanium oxide, ruthenium oxide, iridium oxide or tantalum oxide.

8. The method of claim 1, wherein the first major surface of the at least one substrate has an n-type polarity.

9. The method of claim 1, wherein the first major surface of the at least one substrate is covered with a masking material which is at least largely insoluble in the electrolyte and one or more portions of the first major surface of the at least one substrate contact the electrolyte through openings in the masking material.

10. The method of claim 1, wherein the electrode includes a contact that contacts the first major surface of the at least one substrate.

11. The method of claim 1, wherein the electrode includes an electrically conductive surface portion having a substantially planar surface portion.

12. The method of claim 1, further comprising applying a sealing material at an edge region of the at least one substrate whereby a seal is established which prevents penetration of the electrolyte to at least a portion of the second major surface of the at least one substrate.

13. The method of claim 12, wherein the sealing material is applied at an edge surface region of the first major surface of the at least one substrate.

14. The method of claim 12, wherein the sealing material is applied at an edge surface region of the second major surface of the at least one substrate.

15. The method of claim 12, wherein the support structure includes a groove at an edge portion of the substrate and wherein a portion of the sealing material is positioned within the groove.

16. The method of claim 1, wherein the first major surface of the at least one substrate is coated with a transparent conductive oxide (TCO) material.

17. The method of claim 1, wherein the electrode is one of two or more electrodes and the method comprises:
providing two or more substrates each having opposite first and second major surfaces;
attaching the two or more substrates to the support structure such that each electrode of the two or more electrodes is in electrical contact with one of the two or more substrates;
contacting the two or more substrates and the counter electrode with the electrolyte; and
passing an electrical current through the electrolyte between the first major surface of each substrate and counter electrode such that the metal is deposited at at least some areas of the first major surface of each substrate.

18. The method of claim 17, wherein the at least two substrates are positioned such that the second surfaces of at least two substrates face in opposite directions.

19. The method of claim 1, wherein the metallic material comprises copper.
